(19) United States
(12) Patent Application Publication
(10) Pub. No.: US 2007/0072369 A1
(43) Pub. Date: Mar. 29, 2007

(54) NON-VOLATILE MEMORY AND FABRICATING METHOD THEREOF

(76) Inventors: Rex Young, Hsinchu City (TW); Pin-Yao Wang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,213

(22) Filed: Dec. 20, 2005

(30) Foreign Application Priority Data
Sep. 28, 2005 (TW) 94133689

(51) Int. Cl. H01L 21/336; H01L 29/788

(52) U.S. Cl. 438/257; 438/263; 438/264; 257/315

(57) ABSTRACT

A non-volatile memory includes a substrate, a plurality of isolation layers, a plurality of active layers, a plurality of floating gates, a plurality of control gates and a plurality of doped regions. The active layers are disposed in the substrate between the isolation layers, and the top surface of the active layer is higher than that of the isolation layer. The active layers and the isolation layers are arranged in parallel to each other and extend in the first direction. The control gates are disposed in the substrate. The control gates are arranged in parallel and extend in the second direction which crosses the first direction. The floating gates are disposed between the active layers and the control gates. The doped regions are disposed in the active layers between the control gates.

### CROSS-REFERENCE TO RELATED APPLICATION

This application claims the priority benefit of Taiwan application serial no. 94133689, filed on Sep. 28, 2005. All disclosure of the Taiwan application is incorporated herein by reference.

### BACKGROUND OF THE INVENTION

1. Field of Invention

The present invention relates to a semiconductor device and fabricating method thereof. More particularly, the present invention relates to a non-volatile memory and fabricating method thereof.

2. Description of Related Art

As the flash memory in the non-volatile memory has advantages such as quick and time-saving operation and low cost, it has been one of the main research subjects in the field of art. The typical flash memory mainly includes floating gates and control gates. The control gate is directly disposed on the floating gate. A dielectric layer is disposed between the floating gate and the control gate to separate them, and a tunnel oxide layer is disposed between the floating gate and the substrate to separate them.

The current flash memory array generally used in the field includes NOR array structure and NAND array structure. The flash memory structure of the NAND array connects each memory unit in series, and the integrity and area utilization are better than the flash memory of the NOR array. Accordingly, the flash memory structure of the NAND array has been widely applied in various electronic devices.

However, along with the development of the technology of integrated circuit, in order to micro-minimize the electronic product gradually, the integrity of the internal devices must be improved continuously, so that the size of the memory unit is required to be smaller and smaller, and the distance between the memory units is to be shorter and shorter. Accordingly, the impact of the short channel effect may be more remarkable, which not only changes the on-voltage Vt resulting in the problem of the switch of the path controlled by the gate voltage Vg, but also causes heat electronic effect and punch through effect that a leakage current may be produced in the path or an electrical breakdown may occur. These problems are adverse for the stability and reliability of the memory unit.

In addition, as the size of the memory cell is reduced and the area of the capacitor between the control gate and the floating gate is also shrunken, consequently the coupling coefficient of the control gate will drop. As a result, a greater voltage is needed while operating the memory cell. The increase of the operation voltage may lead to more problems such as heat dissipation or noise signal, etc.; and the power consumption may also be increased.

### SUMMARY OF THE INVENTION

Accordingly, the present invention is directed to provide a non-volatile memory unit which avoids the impact of the short channel effect and improves the reliability and stability of the memory unit, and also, the operation voltage can be lowered and the power consumption is reduced.

Another objective of the present invention is to provide a fabricating method of non-volatile memory, which simplifies the fabricating process, improves the process window and produces memories with higher efficiency.

The present invention provides a non-volatile memory, at least including: a substrate, a plurality of isolation layers, a plurality of active layers, a plurality of floating gates, a plurality of control gates and a plurality of doped regions. The isolation layers are disposed in the substrate. The active layers are disposed in the substrate and between the isolation layers, and the top surface of the active layer is higher than that of the isolation layer. The active layers and the isolation layers are arranged in parallel to each other and extend in the first direction. The control gates are disposed in the substrate. The control gates are arranged in parallel to each other and extend in the second direction which crosses the first direction. The floating gates are disposed between the active layers and the control gates, respectively. The doped regions are disposed in the active layers between the control gates.

In the non-volatile memory according to the embodiment of the present invention, the non-volatile memory further includes a plurality of tunneling dielectric layers disposed between the floating gate and the active layer, wherein the tunneling dielectric layers are in a converse U shape and cover the active layer protruding out the surface of the isolation layer.

The non-volatile memory according to the embodiment of the present invention further includes a plurality of inter-gate dielectric layers, presenting in a converse U shape, disposed between the control gate and the floating gate. The material of the inter-gate dielectric layers includes silicon oxide-silicon nitride-silicon oxide.

In the non-volatile memory according to the embodiment of the present invention, the floating gates presenting in a converse U shape are disposed on the top surface and sidewalls of the active layers. The floating gates are disposed on the two sidewalls of the active layers.

In the non-volatile memory according to the embodiment of the present invention, the substrate includes a silicon-on-insulator substrate.

The non-volatile memory according to the embodiment of the present invention is an NAND flash memory.

The present invention provides a fabricating method of non-volatile memory. First, a substrate is provided. Then, a plurality of isolation layers is formed in the substrate to define a plurality of active layers. The active layers and the isolation layers are arranged in parallel to each other and extend in the first direction. Next, a plurality of grooves is formed in the isolation layer and extends in the second direction to expose the top surface of the active layers, wherein the second direction crosses the first direction. Next, a plurality of floating layers is formed to cover the active layers exposed along the second direction. Next, a plurality of control gates is formed, wherein the control gates cover the floating gate and fill up the grooves, and the control gates are arranged in parallel to each other and extend in the second direction. Next, a plurality of doped regions is formed in the active layers between the control gates.

The fabricating method of non-volatile memory according to the embodiment of the present invention further includes a step of forming a tunneling dielectric layer on the substrate between the step of forming the isolation layers and the step of forming the floating gates. An inter-gate dielectric layer is further formed on the substrate between the steps of forming the above described floating gates and the control gates.

In the fabricating method of non-volatile memory according to the embodiment of the present invention, the step of forming a plurality of grooves in part of the isolation layers in the second direction to expose the top surface of the active layers includes: for example, first, a plurality of mask layers is formed on the surfaces of the isolation layers, wherein the mask layers are arranged in parallel to each other and extend in the second direction; next, using the mask layers as mask, the top surface exposed on the isolation layer is removed, and the grooves are formed in the isolation layers to expose part of the top surface of the active layers.

In the fabricating method of non-volatile memory according to the embodiment of the present invention, the step of forming the floating gates includes: first, a first conductive layer is formed on the substrate; next, a sacrificial layer is formed on the first conductive layer. Next, the sacrificial layer on the mask layer is removed to expose the first conductive layer on the mask layer. Next, the first conductive layer exposed on the two sides of the mask layer is removed. Next, the sacrificial layer on the active layer is removed to expose the first conductive layer on the active layer. Next, the sacrificial layer and part of the first conductive layer on the bottom of the groove are removed.

In the fabricating method of non-volatile memory according to the embodiment of the present invention, the sacrificial layer and the first conductive layer have different etching selectivity.

In the fabricating method of non-volatile memory according to the embodiment of the present invention, the step of removing the sacrificial layer in the groove and part of the first conductive layer in the bottom of the groove includes: for example, first, a dielectric layer is formed on the surface of the first conductive layer exposed on the active layer; next, the sacrificial layer in the groove is removed. Then, using the dielectric layer as mask, the exposed first conductive layer is removed.

The fabricating method of non-volatile memory according to the embodiment of the present invention further includes: the first conductive layer on the top surface of the active layer is removed; accordingly, the first conductive layer is separated at the two sidewalls of the active layer.

In the fabricating method of non-volatile memory according to the embodiment of the present invention, the step of forming the control gates includes, for example, first, a second conductive layer is formed on the substrate; next, a patterned photoresist layer is formed on the substrate to cover the floating gates. The patterned photoresist layers are arranged in parallel to each other and extend in the second direction. Next, using the patterned photoresist layer as mask, part of the second conductive layer is removed. Next, the patterned photoresist layer is removed. Wherein, using the mask layer as the etching stop layer, part of the second conductive layer can be removed. After part of the second conductive layer is removed, the fabricating method further includes removing the mask layer.

In the fabricating method of non-volatile memory according to the embodiment of the present invention, the substrate includes a silicon-on-insulator substrate.

The present invention further provides another fabricating method of non-volatile memory. First, a substrate is provided; a plurality of isolation layers is formed in the substrate, so that a plurality of active layers is defined; the active layers and the isolation layers are arranged in parallel to each other and extend in a first direction. Next, a plurality of mask layers is formed on the substrate, and the mask layers are arranged in parallel to each other and extend in a second direction which crosses the first direction. Next, using the mask layer as mask, the top surface exposed on the isolation layer is removed, and a plurality of grooves is formed in the isolation layer. These grooves are arranged along the second direction to expose the top surface of the active layer. Next, a tunneling dielectric layer is formed on the active layer. Next, a first conductive layer and a sacrificial layer are formed on the substrate in sequence.

Then, the sacrificial layer on the mask layer is removed to expose the first conductive layer on the mask layer. Next, the first conductive layer exposed on the two sides of the mask layer is removed. Next, the sacrificial layer on the active layer is removed to expose the first conductive layer on the active layer, and a dielectric layer is formed on the surface of the first conductive layer exposed on the active layer. Next, the exposed sacrificial layer is removed. Then, using the dielectric layer as mask, part of the first conductive layer in the bottom of the groove is removed.

Then, an inter-gate dielectric layer and a second conductive layer are formed on the substrate in sequence. Next, the second conductive layer is patterned, so that the second conductive layer is stripped and covers the first conductive layer. The second conductive layers are arranged in parallel to each other and extend in the second direction. Next, the mask layer is removed, and a plurality of doped regions is formed in the active layers between the second conductive layers.

The fabricating method of non-volatile memory according to the embodiment of the present invention further includes: the first conductive layer on the active layer is removed after the sacrificial layer on the active layer is removed and before the dielectric layer is formed.

In the fabricating method of non-volatile memory according to the embodiment of the present invention, the step of removing the exposed first conductive layer is, for example, by using etching back.

In the fabricating method of non-volatile memory according to the embodiment of the present invention, the step of removing the sacrificial layer on the active layer includes: for example, first, a photoresist is filled into the concavity of the sacrificial layer; next, the etching back process is preformed to remove the sacrificial layer of the active layer. Then, the photoresist is removed to complete the process.

In the fabricating method of non-volatile memory according to the embodiment of the present invention, the step of removing the sacrificial layer on the active layer can also be chemical-mechanical polishing process.

In the fabricating method of non-volatile memory according to the embodiment of the present invention, the step of removing the exposed sacrificial layer includes, for example, by using wet etching. The step of removing part of the first conductive layer in the bottom of the groove includes by using etching back.

In the fabricating method of non-volatile memory according to the embodiment of the present invention, the step of patterning the second conductive layer includes: for example, first, a patterned photoresist layer is formed on the substrate to cover the first conductive layer. The patterned photoresist layers are arranged in parallel to each other and extend in the second direction. Next, using the patterned photoresist layer as mask, part of the second conductive layer is removed. Next, the patterned photoresist layer is removed.

In the fabricating method of non-volatile memory according to the embodiment of the present invention, the step of removing the mask layer includes, for example, by using wet etching.

In the fabricating method of non-volatile memory according to the embodiment of the present invention, the step of forming the tunneling dielectric layer, inter-gate dielectric layer or dielectric layer includes, for example, by using thermal oxidation.

In the fabricating method of non-volatile memory according to the embodiment of the present invention, the step of removing the sacrificial layer on the mask layer includes, for example, by using chemical-mechanical polishing process.

As the present invention applies the fin-shaped active layer, and the floating gate and the control gate which cover the active layer, the impact of short channel effect can be avoided; the reliability and stability of the memory are improved; the operation voltage is lowered; and the power consumption is reduced.

The fabrication method of non-volatile memory according to the present invention not only simplifies the fabrication process, but also reduces the fabrication cost; further, the fabrication process window is improved and the memory with higher efficiency can be made.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are the top views of a fabricating process of a non-volatile memory according to one embodiment of the present invention.

FIGS. 2A-2F are cross-sectional schematic diagrams of FIGS. 1A-1F along line I-I′, respectively.

FIG. 3E and FIG. 3F are cross-sectional schematic diagrams of FIG. 1E and FIG. 1F along line II-II′, respectively.

FIG. 1G is a top view of a fabricating process of a non-volatile memory according to another embodiment of the present invention.

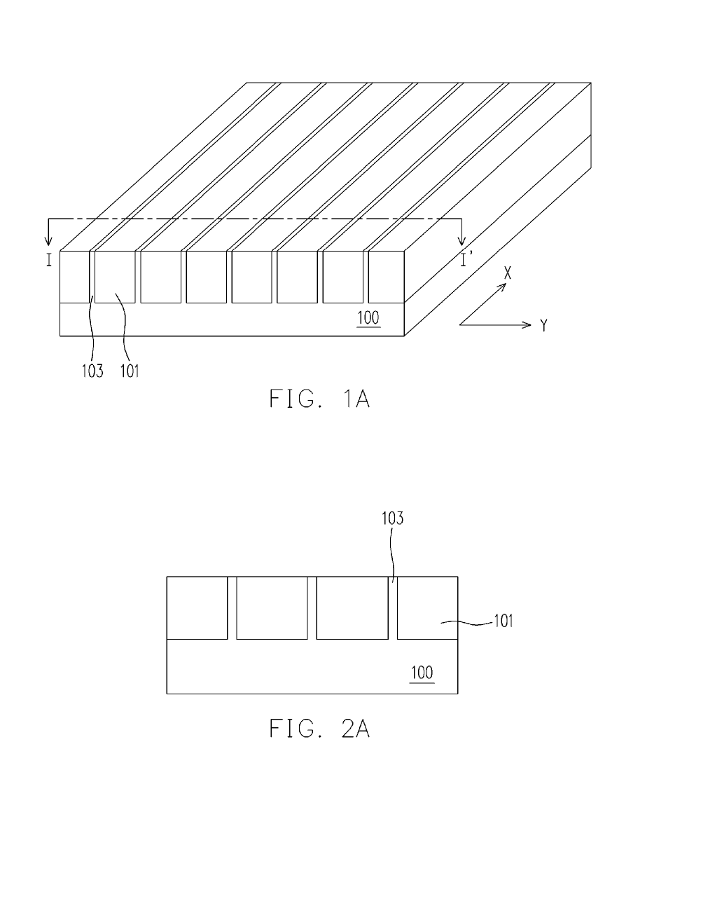

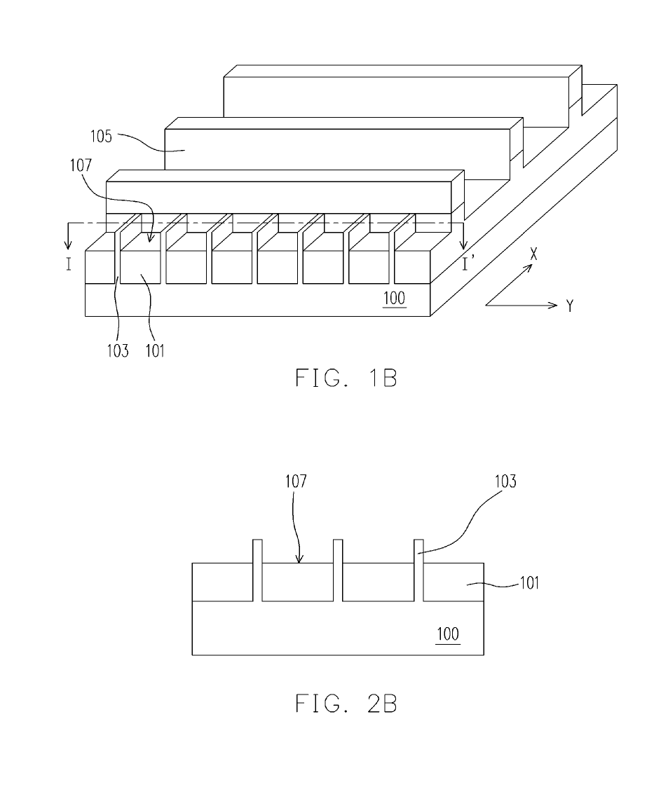

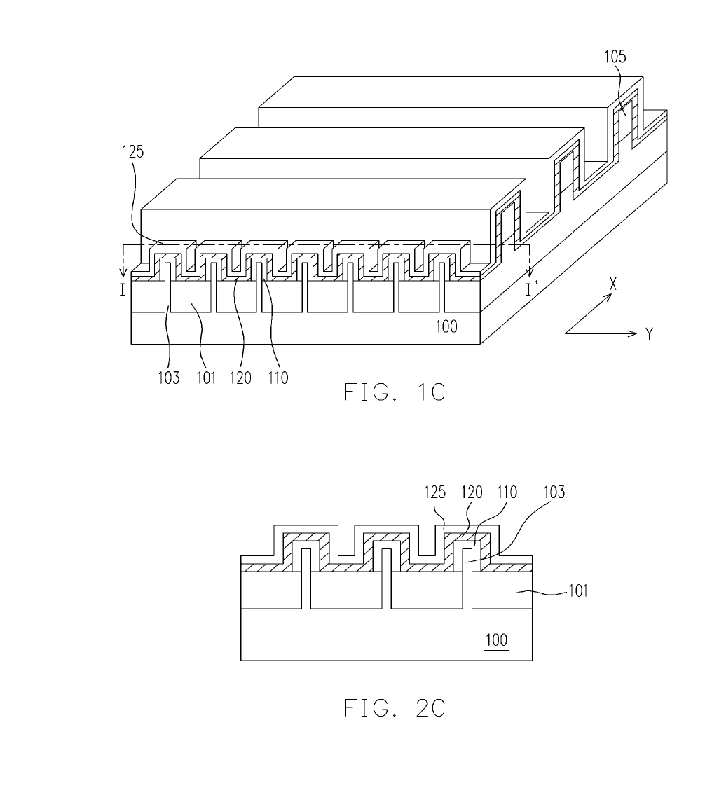

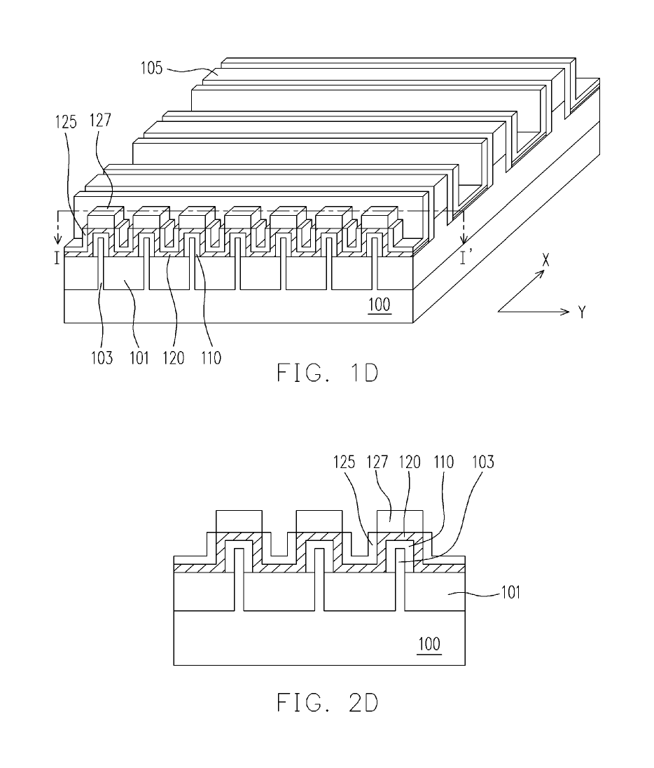

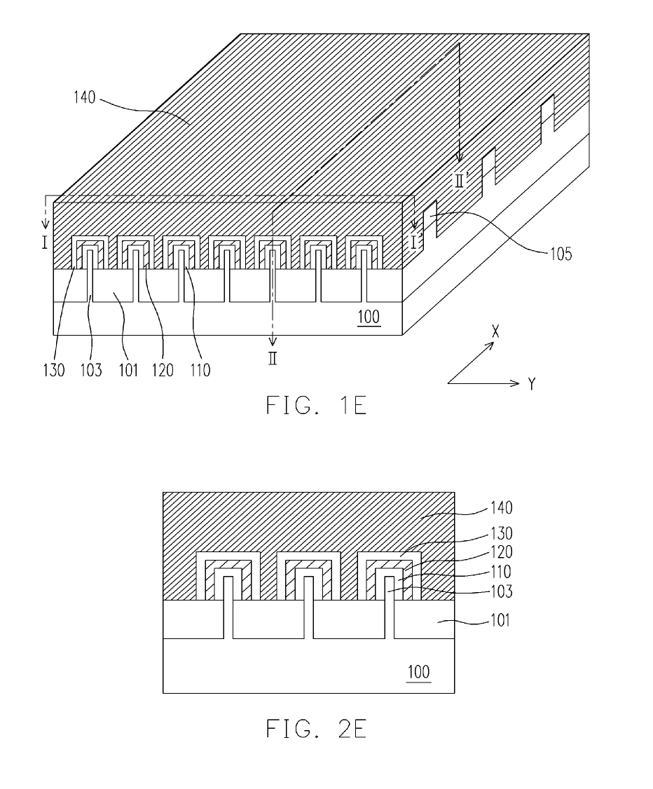

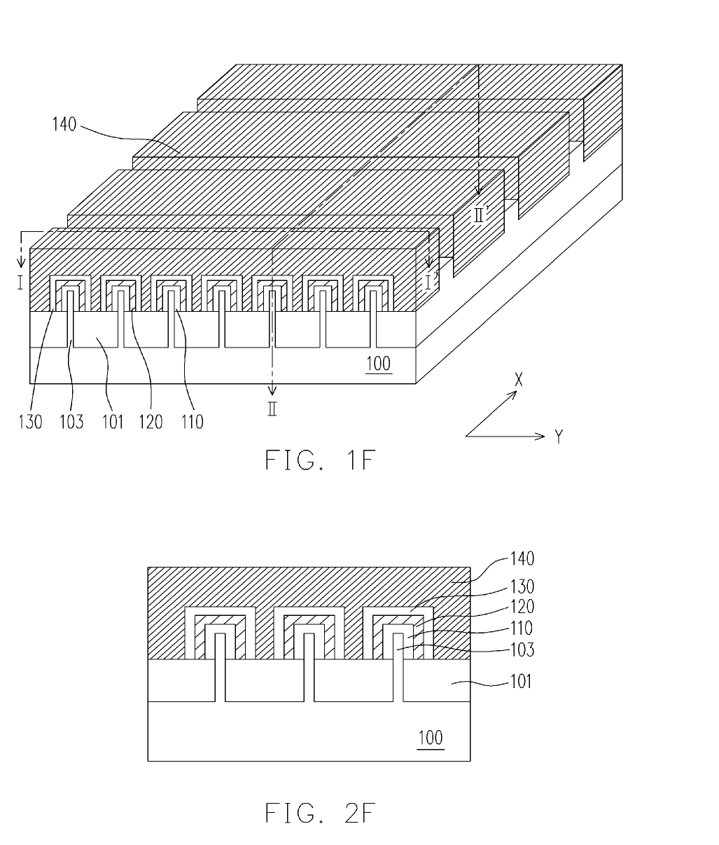

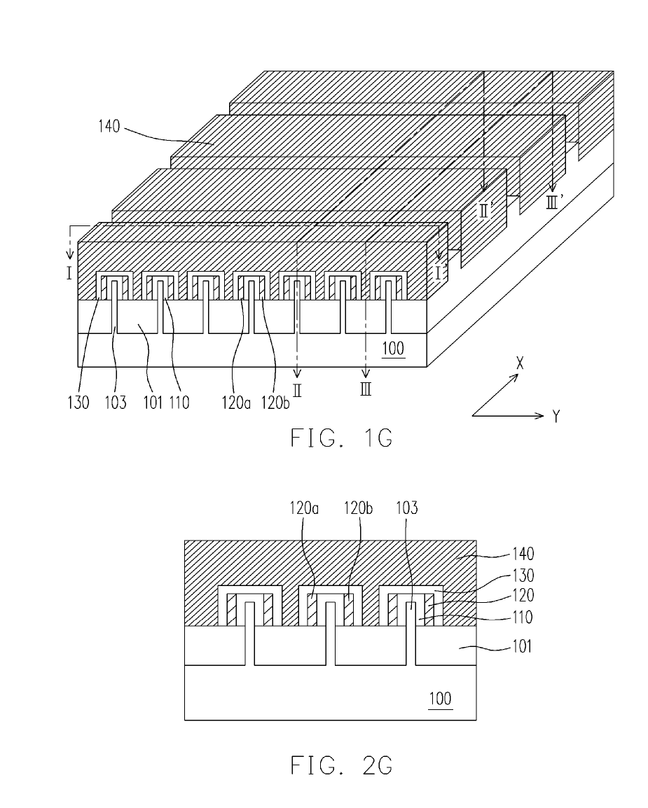

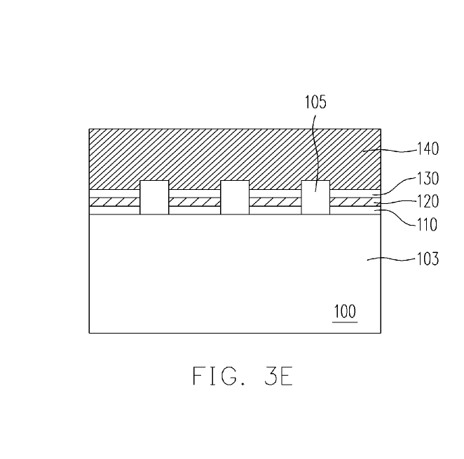

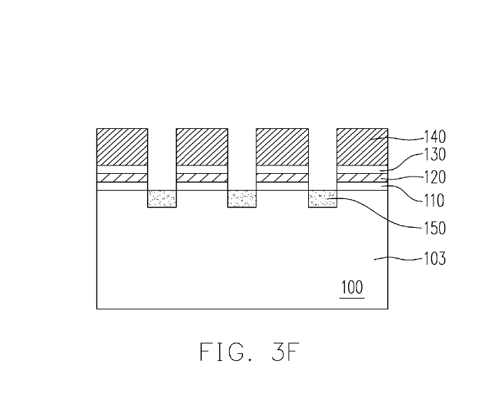

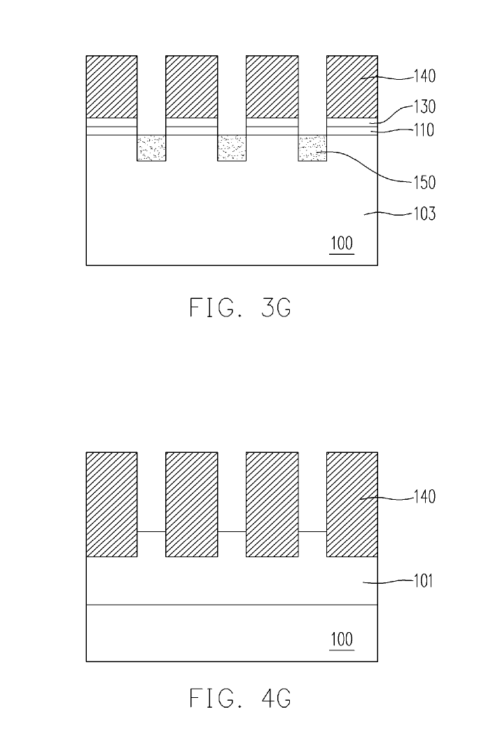

FIG. 2G, FIG. 3G and FIG. 4G are cross-sectional schematic diagrams of FIG. 1G along lines I-I′, II-II′, and II-II′, respectively.

### DESCRIPTION OF EMBODIMENTS

FIG. 1A to FIG. 1F are tri-dimensional views of a fabricating process of the non-volatile memory according to one embodiment of the present invention. FIGS. 2A-2F are cross-sectional diagrams of the structures in FIGS. 1A-1F along line I-I′, respectively. FIG. 3E and FIG. 3F are cross-sectional diagrams of the structures in FIG. 1E and FIG. 1F along line II-II′, respectively.

Referring to FIG. 1A and FIG. 2A, the present invention provides a fabricating method of non-volatile memory, by which an NAND flash memory can be formed. First, a substrate 100 is provided; a plurality of isolation layers 101 is formed on the substrate 100; a plurality of active layers 103 is defined between each isolation layer 101; the active layers 103 and the isolation layers 101 are arranged in parallel to each other and extend in X direction. The substrate 100 is, for example, silicon substrate, or silicon on insulator. The formation method of the isolation layer 101 includes: for example, first, a plurality of trenches (not shown) is formed on the substrate 100; then, the suitable dielectric materials are filled into the trenches to form the isolation layer 101.

Next, referring to FIG. 1B and FIG. 2B, a plurality of mask layers 105 are formed on the substrate 100, and the mask layers 105 are arranged in parallel to each other and extend in Y direction. The forming method of the mask layers 105 includes: for example, first, a mask material layer (not shown) is formed on the substrate 100; next, a patterned photoresist layer (not shown) is formed; next, using the patterned photoresist layer as mask, part of the mask material layer is removed to form the mask layer 105. The material of the mask layer 105 (the mask material layer) is, for example, silicon nitride or other suitable materials with different etching selectivity from the isolation layers 101; and the formation method is, for example, chemical vapor deposition. The method of removing part of mask material layer is, for example, anisotropic etching process.

Next, part of the isolation layer 101 is removed; a plurality of grooves 107 is formed in the isolation layer 101, and the grooves 107 are arranged in parallel to each other and extend in Y direction, so that the top surface of the active layer 103 along Y direction is exposed. The formation method of the grooves 107 includes: selecting the reaction gas which can etch the isolation layer 101, but can not etch the active layer 103, using the mask layer 105 as etching mask, the grooves 107 are formed by anisotropic etching process.

Next, referring to FIG. 1C and FIG. 2C, a tunneling dielectric layer 110, a conductive layer 120 and a sacrificial layer 125 are formed on the substrate 100 in sequence. The material of the tunneling dielectric layer 110 is, for example, silicon oxide, and the formation method is, for example, thermal oxidation. The material of the conductive layer 120 is, for example, doped polysilicon, and the formation method includes: for example, after an undoped polysilicon layer is formed by chemical vapor deposition, the conductive layer 120 is formed by an ion-implanting process; or, using in situ doped material implanting, the conductive layer 120 can also be formed by chemical vapor deposition. The formation of the sacrificial layer 125 is to define the conductive layer 120 as the floating gate in the subsequent processes. Therefore, the material of the sacrificial layer 125, for example, should have different etching selecting ratio from that of the conductive layer 120, such as silicon nitride. The formation method of the sacrificial layer 125 is, for example, chemical vapor deposition.

Next, referring to FIG. 1D and FIG. 2D, part of the sacrificial layer 125 on the mask layer 105 is removed to expose the top surface of the conductive layer 120 on the mask layer 105. The method of removing the sacrificial layer 125 includes, for example, chemical-mechanical polishing process. Next, the conductive layer 120 exposed in the above processes is removed, and the removing method is, for example, dry or wet etching back process. Since the other structures are covered by the sacrificial layer 125, the etching process is to remove the conductive layer 120 over the mask layer 105 and the conductive layer 120 between the sidewall of the mask layer 105 and the sacrificial layer 125. Accordingly, after the etching process, the entire layer of the conductive layer 120 is separated into stripes which are arranged in parallel to each other along Y direction.

Next, the sacrificial layer 125 on the active layer 103 is removed until the top surface of the conductive layer 120 over the active layer 103 is exposed. The method of removing the sacrificial layer 125 is, for example, chemical-mechanical polishing process, and part of the mask layer 105 and the sacrificial layer 125 on the two sides thereof are abraded off at the same time, so that the XY planes have the same heights; or, first, a polymer or photoresist (not shown) is filled into the space between the sacrificial layers 125, then, the sacrificial layers 125 are removed by dry or wet etching back process, and, at the same time, part of the mask layer 105 and the sacrificial layer 125 at two sides of the mask layer 105 are removed. Then, a dielectric layer 127 is formed on the exposed conductive layer 120. The material of the dielectric layer 127 should have different etching selectivity from that of the sacrificial layer 125 and the conductive layer 120. The method of forming the dielectric layer 127 is, for example, thermal oxidation by which the exposed part of the conductive layer 120 is oxidized into silicon oxide. Of course, the material of the dielectric layer 127 can also be other suitable dielectric material which is suitable to be the etching mask layer for etching the sacrificial layer 125 and the conductive layer 120.

Next, referring to FIG. 1E, FIG. 2E and FIG. 3E, the sacrificial layer 125 on the conductive layer 120 is removed, and the removing method is, for example, wet etching. At the same time, part of the mask layer 105 and the sacrificial layer 125 on the two sides of the mask layer 105 are removed. Then, part of the conductive layers 120 in the bottom of the grooves 107 are removed, and the removing method is, for example, by etching back process using the dielectric layer 127 as mask. Accordingly, the striped conductive layers 120 are separated, so that the conductive layers 120 on the active layer 103 are isolated to each other to form the converse U shaped floating gates (the conductive layers 120) which cover the exposed top surface of the active layer 103.

Next, an inter-gate dielectric layer 130 and another conductive layer 140 are formed on the substrate 100 in sequence. The material of the inter-gate dielectric layer 130 is, for example, silicon oxide-silicon nitride-silicon oxide, and the formation method includes: using chemical vapor deposition, the silicon oxide layer, silicon nitride layer and silicon oxide layer are formed in sequence by different reaction gases. Of course, the material of the inter-gate dielectric layer 130 can also be suitable dielectric materials such as silicon oxide, silicon nitride, or silicon oxide-silicon nitride, etc. The material of the conductive layer 140 is, for example, conductive materials such as doped polysilicon, metal, or metal silicide, etc., and the formation method is, for example, by chemical vapor deposition or physical vapor deposition according to different materials.

Next, referring to FIG. 1F, FIG. 2F, and FIG. 3F, the conductive layer 140 is patterned to form striped control gates. The method of patterning the conductive layer 140 includes: for example, first, a patterned photoresist layer (not shown) is formed on the conductive layer 140, and the photoresist layer covers the conductive layer 120; then, the conductive layer 140 between the patterned photoresist layers is removed by dry etching. It can be known from FIG. 3E that the mask layer 105, left from the foregoing processes, still remains between the conductive layers 120. The mask layer 105 can be used as the etching stop layer to define the conductive layer 140. Accordingly, even there is deflection of the position of the patterned photoresist layer, the patterned photoresist can still define the striped control gates (the conductive layer 140), further, the process window is improved and the complication of the fabricating process is reduced.

Next, the mask layer 105 is removed, and the removing method is, for example, wet etching. Then, a plurality of doped regions 150 are formed in the active layers between the conductive layers 140. The method of forming the doped regions 150 is, for example, by implanting doped material using the conductive layer 140 as mask. The doped material implanted can be N type or P type doped material, which depends on the device design. It needs to be noticed that, in the subsequent processes, a protection layer (not shown) may be formed on the conductive layer 140 to fill the space between the control gates, so that the mask layer 105 may not be removed, but used as the protection layer for separation. The subsequent fabricating processes of non-volatile memory are well known by those skilled in the art, so that the detail is omitted here.

In the fabricating method of the non-volatile memory, using different etching selectivity between the active layer 103 and the isolation layer 101, a plurality of grooves 105 are formed along Y direction to expose the top surface of the active layer 103. The active layer 103 protruding out of the isolation layer 101 can be formed more accurately by the method. The formation of the fin-shaped active layer 103 can be better controlled, and the difficulty of the fabricating process is reduced.

Moreover, the formation of the floating gate (the conductive layer 120) is completed using the sacrificial layer 125 and the dielectric layer 127, and the photolithography etching process is not needed, so that the fabricating cost is reduced and the fabricating process is shortened. In addition, although the formation of the control gate (the conductive layer 140) may need a light mask, using the mask layer 105 as the etching stop layer, larger process window is accepted in the photolithography process, so that the process window is improved.

FIG. 1G is a tri-dimensional view of a non-volatile memory according to another embodiment of the present invention. FIG. 2G, FIG. 3G and FIG. 4G are cross-sectional schematic diagrams of FIG. 1G along lines I-I′, II-II′, and II-II′, respectively.

Referring back to FIG. 2D, the conductive layer 120 on the active layer 103 can also be removed before the dielectric layer 127 is formed or after the converse U shaped conductive layer 120 is defined on the two sides of the active layer 103, so that the conductive layer 120 is separated into a conductive layer 120a and a conductive layer 120b, and two independent floating gates are formed on the two sides of the active layer. The method of removing part of the conductive layer 120 includes, for example, etching back or chemical-mechanical polishing process. In the formed non-volatile memory as shown in FIG. 1G, FIG. 2G, FIG. 3G, and FIG. 4G, the conductive layer 120a and the conductive layer 120b are disposed on the two sides of the active layer 103, respectively.

The conductive layers 120a, 120b in the embodiment are block shaped, disposed on the two sides of the active layer 103. The fabricating process is not complicated, and the formation of the conductive layers 120a, 120b is easy, so that the design of the devices can be various to meet the requirements of the industry.

The following will describe the non-volatile memory formed by the aforementioned fabricating method. FIG. 1F is a tri-dimensional diagram of a non-volatile memory according to one embodiment of the present invention. FIG. 2F and FIG. 3F are the cross-sectional diagrams of the FIG. 1F along lines I-I′ and II-II′, respectively.

Referring to FIG. 1F, FIG. 2F and FIG. 3F, the non-volatile memory can be NAND flash memory, including a substrate 100, a plurality of isolation layers 101, a plurality of active layers 103, a plurality of floating gates 120, a plurality of control gates 140 and a plurality of doped regions 150. The isolation layers 101 are disposed in the substrate 100 to define a plurality of active layers 103. The top surface of the active layers 103 is higher than that of the isolation layers 101. The active layers 103 and the isolation layers 101 are arranged in parallel to each other and extend in X direction. The floating gates 120 is converse U shaped and covers the active layers 103. The control gates 140 cover the floating gates 120. The control gates 140 are arranged in parallel to each other and extend in Y direction. The doped regions 150 are disposed in the active layers 103 between the control gates 140.

The substrate 100 includes, for example, silicon substrate or silicon on isolation (SOI). The material of the isolation layer 101 includes, for example, suitable insulation material such as silicon oxide, etc. The material of the floating gate 120 is, for example, doped polysilicon. The material of the control gate 140 includes, for example, doped polysilicon, metal, or metal silicide. The doped region 150 is, for example, N type doped region or P type doped region.

Wherein, a tunneling dielectric layer 110 is disposed, for example, between the floating gate 120 and the active layer 103. The material of the tunneling dielectric layer 110 is, for example, silicon oxide. An inter-gate dielectric layer 130 is disposed, for example, between the control gate 140 and the floating gate 120. The material of the inter-gate dielectric layer 130 includes, for example, a compound dielectric layer such as silicon oxide-silicon nitride-silicon oxide, etc., or silicon oxide, silicon nitride or compound of other dielectric materials.

As the non-volatile memory applies very thin fin-shaped active layer 103 and the floating gate 120 covering the active layer 103, the leakage current in the path can be eliminated, accordingly, the problem of short channel effect can be avoided.

Moreover, as the non-volatile memory is formed with double gate structure which clamps the active layer 103 with separation of the tunneling dielectric layer 110, the two sidewalls of the entire active layer 103 can induce the electric field produced by the gate, so that the on-current of the devices is increased, and the problem of leakage current is reduced.

In addition, as the floating gate 120 is converse U shaped and covers the active layer 103, and the control gate 140 clamps the entire floating gate 120, so that the area of the capacitor between the control gate 140 and the floating gate 120 is increased in great scale. Accordingly, the couple coefficient of the control gate 140 is improved. Further, the operation voltage of the memory is lowered and the power consumption is reduced.

FIG. 1G is a tri-dimensional diagram of a non-volatile memory according to another embodiment of the present invention. FIG. 2G, FIG. 3G, and FIG. 4G are cross-sectional structure diagrams of the FIG. 1G along lines I-I′, and II-II′. In the embodiment, the floating gates 120a, 120b, as shown in FIG. 1G, FIG. 2G, FIG. 3G, and FIG. 4G, are block shaped, disposed on the left and right sides of the active layer 103, respectively. The configuration of the other devices is the same as those in the former embodiment.

Also, the non-volatile memory according to the embodiment can eliminate the leakage current in the path and avoid the problem of short channel effect. And, the area of the capacitor between the gates is increased and the operation voltage is reduced. In addition, the non-volatile memory further has the function of single memory unit with two bits, so that the layout of the non-volatile memory is more flexible to meet the requirements of the industry.

In summary, the fabricating method of the non-volatile memory of the present invention not only reduces the fabricating cost and shortens the fabricating process, but also better controls the formation of the fin-shaped active layer; moreover, it has the advantage of improving the process window.

In addition, as the shapes and thicknesses of the active layers, the floating gates and the control gates of the non-volatile memory, the short channel effect can be avoided; the problem of leakage current can be prevented; the on-current of the memory is increased; and, the operation voltage of the memory is reduced. These functions are helpful to make the non-volatile memory with better electric performance, reliability, stability and operation speed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, comprising:
a substrate;
a plurality of isolation layers, disposed in the substrate;
a plurality of active layers, disposed in the substrate and between the isolation layers, wherein the top surface of the active layer is higher than that of the isolation layer, and the active layers and the isolation layers are arranged in parallel to each other and extend in a first direction;
a plurality of control gates, disposed in the substrate, wherein the control gates are arranged in parallel and extend in a second direction which crosses the first direction;
a plurality of floating gates, disposed between the active layers and the control gates; and
a plurality of doped regions, disposed in the active layers between the control gates.

2. The non-volatile memory of claim 1, further comprising a plurality of tunneling dielectric layers disposed between the floating gates and the active layers, wherein the tunneling dielectric layers present in a converse U shape and cover the active layers protruding out of the surface of the isolation layers.

3. The non-volatile memory of claim 1, further comprising a plurality of inter-gate dielectric layers, presenting in a converse U shape, disposed between the control gates and the floating gates.

4. The non-volatile memory of claim 3, wherein the material of the inter-gate dielectric layers comprises silicon oxide-silicon nitride-silicon oxide.

5. The non-volatile memory of claim 1, wherein the floating gates present in a converse U shape and are disposed on the top surface and sidewall of the active layers.

6. The non-volatile memory of claim 1, wherein the floating gates are disposed on the two sidewalls of the active layers.

7. The non-volatile memory of claim 1, wherein the substrate comprises a silicon on insulator (SOI) substrate.

8. The non-volatile memory of claim 1, wherein the non-volatile memory is an NAND type flash memory.

9. A fabricating method of non-volatile memory, comprising:
providing a substrate;
forming a plurality of isolation layers in the substrate to define a plurality of active layers, wherein the active layers and the isolation layers are arranged in parallel to each other and extend in a first direction;
forming a plurality of grooves in the isolation layer, wherein the grooves extend in a second direction which crosses the first direction, and expos the top surface of the active layers;
forming a plurality of floating layers to cover the active layers exposed along the second direction;
forming a plurality of control gates to cover the floating gates and fill the grooves, wherein the control gates are arranged in parallel to each other and extend in the second direction; and
forming a plurality of doped regions in the active layers between the control gates.

10. The method of claim 9, further comprising: forming a tunneling dielectric layer on the substrate between the step of forming the isolation layers and the step of forming the floating gates.

11. The method of claim 9, further comprising: forming an inter-gate dielectric layer on the substrate between the step of forming the floating gates and the step of forming the control gates.

12. The method of claim 9, wherein the step of forming a plurality of grooves in the isolation layers in the second direction to expose the top surface of the active layers comprises:
forming a plurality of mask layers on the surfaces of the isolation layers, wherein the mask layers are arranged in parallel to each other and extend in the second direction; and
removing the top surface exposed on the isolation layer by using the mask layers as mask, and forming the grooves in the isolation layers to expose part of the top surface of the active layers.

13. The method of claim 12, wherein the step of forming a plurality of floating gates comprises:
forming a first conductive layer on the substrate;
forming a sacrificial layer on the first conductive layer;
removing the sacrificial layer on the mask layer to expose the first conductive layer on the mask layer;
removing the first conductive layer exposed on the two sides of the mask layer;
removing the sacrificial layer on the active layer to expose the first conductive layer on the active layer; and
removing the sacrificial layer and part of the first conductive layer on the bottom of the groove.

14. The method of claim 13, wherein the sacrificial layer and the first conductive layer have different etching selectivity.

15. The method of claim 14, wherein the step of removing the sacrificial layer in the groove and part of the first conductive layer in the bottom of the groove comprises:
forming a dielectric layer on the surface of the first conductive layer exposed on the active layer;
removing the sacrificial layer in the groove; and
removing the exposed first conductive layer by using the dielectric layer as mask.

16. The method of claim 15, further comprising: removing the first conductive layer on the top surface of the active layer to separate the first conductive layer at the two sidewalls of the active layer.

17. The method of claim 12, wherein the step of forming the control gates comprises:
forming a second conductive layer on the substrate;
forming patterned photoresist layers on the substrate to cover the floating gates, wherein the patterned photoresist layers are arranged in parallel to each other and extend in the second direction;
removing part of the second conductive layer by using the patterned photoresist layers as mask; and
removing the patterned photoresist layers.

18. The method of claim 17, further comprising: removing part of the second conductive layer by using the mask layer as the etching stop layer.

19. The method of claim 18 further comprising: removing the mask layer after the step of removing part of the second conductive layer.

20. The method of claim 9, wherein the substrate comprises a silicon on insulator (SOI) substrate.

21. A fabricating method of non-volatile memory, comprising:
providing a substrate;
forming a plurality of isolation layers in the substrate to define a plurality of active layers, wherein the active layers and the isolation layers are arranged in parallel to each other and extend in a first direction;
forming a plurality of mask layers on the substrate, wherein the mask layers are arranged in parallel to each other and extend in a second direction which crosses the first direction;
removing the top surface exposed on the isolation layer by using the mask layer as mask to form a plurality of grooves in the isolation layers, wherein the grooves are arranged along the second direction to expose the top surface of the active layers;
forming a tunneling dielectric layer on the active layer;
forming a first conductive layer and a sacrificial layer on the substrate in sequence;
removing the sacrificial layer on the mask layer to expose the first conductive layer on the mask layer;
removing a first conductive layer exposed on the two sides of the mask layer;
removing the sacrificial layer on the active layer to expose the first conductive layer on the active layer;
forming a dielectric layer on the surface of the first conductive layer exposed on the active layer;
removing the exposed sacrificial layer;
removing part of the first conductive layer in the bottom of the groove by using the dielectric layer as mask;
forming an inter-gate dielectric layer and a second conductive layer on the substrate in sequence;
patterning the second conductive layer to form stripped-like the second conductive layer and cover the first conductive layer, wherein the second conductive layers are arranged in parallel to each other and extend in the second direction;
removing the mask layer; and
forming a plurality of doped regions in the active layer between the second conductive layers.

22. The method of claim 21, further comprising: removing the first conductive layer on the active layer after the step of removing the sacrificial layer on the active layer and before the step of forming the dielectric layer.

23. The method of claim 21, wherein the step of removing the exposed first conductive layer comprises by using etching back process.

24. The method of claim 21, wherein the step of removing the sacrificial layer on the active layer comprises:
filling a photoresist into the concavity of the sacrificial layer;
performing a etching back process to remove the sacrificial layer of the active layer; and
removing the photoresist.

25. The method of claim 21, wherein the step of removing the sacrificial layer on the active layer comprises by using chemical-mechanical polishing process.

26. The method of claim 21, wherein the step of removing the exposed sacrificial layer comprises by using wet etching method.

27. The method of claim 21, wherein the step of removing part of the first conductive layer in the bottom of the groove comprises by using etching back process.

28. The method of claim 21, wherein the method of patterning the second conductive layer comprises:
forming patterned photoresist layers on the substrate to cover the first conductive layer, wherein the patterned photoresist layers are arranged in parallel to each other and extend in the second direction;
removing part of the second conductive layer by using the patterned photoresist layer as mask; and
removing the patterned photoresist layer.

29. The method of claim 21, wherein the step of removing the mask layer comprises by using wet etching method.

30. The method of claim 21, wherein the step of forming the tunneling dielectric layer comprises by using thermal oxidation.

31. The method of claim 21, wherein the step of forming the inter-gate dielectric layer comprises by using thermal oxidation.

32. The method of claim 21, wherein the step of forming the dielectric layer comprises by using thermal oxidation.

33. The method of claim 21, wherein the step of removing the sacrificial layer on the mask layer comprises by using chemical-mechanical polishing process.
